(19) United States
(12) Patent Application Publication
(10) Pub. No.: US 2024/0332436 A1
(43) Pub. Date: Oct. 3, 2024

(54) OPTICAL SENSOR PACKAGE WITH LIGHT SHIELDING MATERIAL

(71) Applicant: STMicroelectronics International N.V., Geneva (CH)

(72) Inventors: Yiying KUO, Taoyuan (TW); David GANI, Choa Chu Kang (SG); Hui-Tzu WANG, Zhubei (TW)

(73) Assignee: STMicroelectronics International N.V., Geneva (CH)

(21) Appl. No.: 18/607,211

(22) Filed: Mar. 15, 2024

Related U.S. Application Data
(60) Provisional application No. 63/492,983, filed on Mar. 29, 2023.

(51) Int. Cl. H01L 31/0216; H01L 31/02; H01L 31/0203

(52) U.S. Cl. CPC H01L 31/02164; H01L 31/02005; H01L 31/0203

(57) ABSTRACT

The present disclosure is directed to an optical sensor package with light shielding material covering five sides. The optical sensor package includes a transparent layer, a substrate layer, sensor elements between the transparent layer and the substrate layer, a first layer of light shielding material on the side of the substrate layer opposite the transparent layer, and a second layer of light shielding material covering five sides of the optical sensor package. The first and second layers of light shielding material prevent light from entering the sides of the optical sensor package or from traveling through the substrate layer and reflecting toward the sensor elements.

### BACKGROUND

### Technical Field

The present disclosure relates to a light shielding packaging for an optical sensing device.

### Description of the Related Art

Optical sensors packages are devices capable of converting light rays into electronic signals. Typically, optical sensor packages are a cavity type package with a glass layer on a Bismaleimide Triazine (BT) substrate and a cavity or space between the glass layer and a semiconductor chip on the BT substrate. In operation, light entering the optical sensor package through the glass layer is detected by the semiconductor chip, whereas light directed at the BT substrate on the sides of the cavity is blocked from entering the cavity and from being detected by the semiconductor chip. This reduces light interference, which optimizes performance of the optical sensor.

However, known optical sensor packages suffer from a key disadvantage. For example, the presence of the cavity in the package results in packages with a larger size, which is counter to general market trends towards smaller electronic devices. In other words, in modern electronic devices, space is at a premium, which makes larger packages significantly less preferable. In some products, low profile optical sensor packages have form factor of an electronic device and thus larger packages may not be usable.

### BRIEF SUMMARY

The present disclosure is directed to an optical sensor package with light shielding material covering five sides. More specifically, the optical sensor package includes a transparent layer on a substrate layer with sensor elements between the transparent layer and the substrate layer. While an outer surface of the transparent layer remains uncovered, each of the five other surfaces of the optical sensor package are covered in a layer of light shielding material. The transparent layer may be glass.

The layer of light shielding material on the sidewalls of the optical sensor package prevents light from entering the optical sensor package through the sidewalls of the transparent layer and being detected by the sensor elements. Additionally, the layer of light shielding material on the face of the optical sensor package opposite the uncovered face prevents light from traveling through the substrate layer and reflecting toward the sensor elements. When the sensor elements detect light from the sidewalls or light reflecting through the substrate layer, unnecessary signal noise is generated which affects performance of the optical sensor package.

The present disclosure overcomes the drawbacks of the prior art. Since the sidewalls of the transparent or glass layer are covered by the layer of light shielding material, a cavity within the package can be eliminated. Thus, the optical sensor package of the present disclosure can retain a smaller size, while preventing light from entering through the sidewalls and substrate layer of the optical sensor package.

### BRIEF DESCRIPTION OF THE SEVERAL VIEWS OF THE DRAWINGS

For a better understanding of the present disclosure, one or more embodiments will now be described by way of example only, with reference to the accompanying drawings. In the drawings, identical reference numbers identify similar elements or acts. In some figures, the structures are drawn exactly to scale. In other figures, the sizes and relative positions of elements in the drawings are not necessarily drawn to scale. For example, the sizes, shapes of various elements and angles may be enlarged and positioned in the figures to improve drawing legibility.

FIG. 1 is a cross-sectional view of an optical sensor package with light shielding material covering five sides.

FIGS. 2A-2F are cross-sectional views of an embodiment of a method of assembling the optical sensor package in FIG. 1.

### DETAILED DESCRIPTION

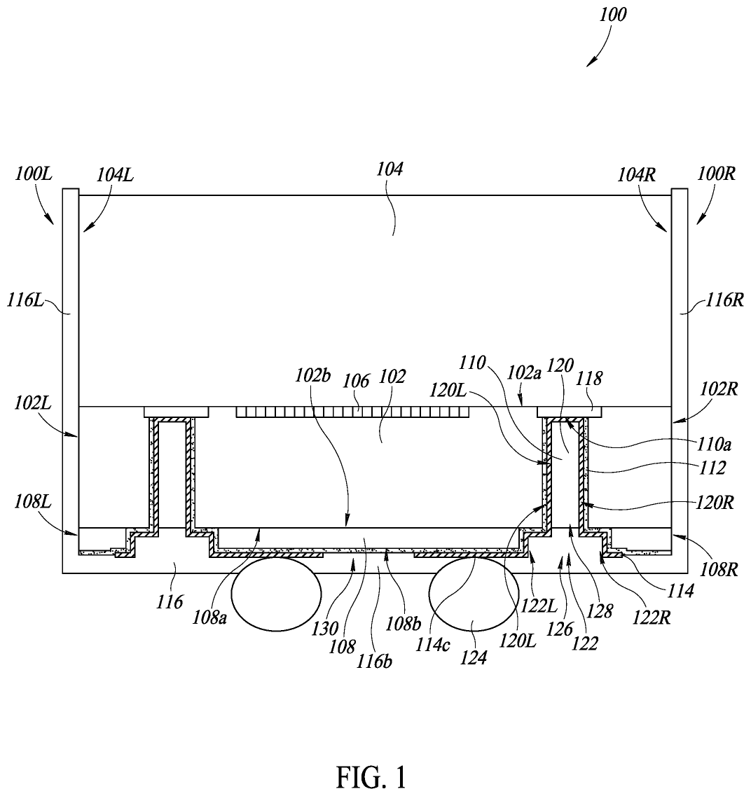

FIG. 1 is an electronic device 100 including a substrate layer 102 and a transparent layer 104 on the substrate layer 102. Sensor elements 106 are embedded or otherwise formed in the substrate layer 102 in a first surface 102a and positioned between the first surface 102a of the substrate layer 102 and the transparent layer 104. A first, inner layer of light shielding material 108 covers a second surface 102b of the substrate layer 102.

The through silicon vias (TSVs) 110 extend from the second surface 102b to the first surface 102a of the substrate layer 102. A second, outer layer of light shielding material 116 entirely covers the bottom surface and sidewalls of electronic device 100. The outer layer of light shielding material 116 is spaced from the second surface 102b of the substrate layer 102 by the first layer of light shielding material. Although not shown in the cross-sectional view, all four lateral sidewalls of the electronic device 100 are covered by the outer layer of light shielding material 116. The four lateral sidewalls include a first sidewall 100L and a second sidewall 100R in FIG. 1. The first sidewall 100L includes a first sidewall 102L of the substrate layer 102, a first sidewall 104L of the transparent layer 104, and a first sidewall 108L of the first layer of light shielding material 108. The first sidewall 102L of the substrate layer 102, the first sidewall 104L of the transparent layer 104, and the first sidewall 108L of the first layer of light shielding material 108 are coplanar. The first sidewall 100L is covered by a first portion 116L of the outer layer of light shielding material 116. The second sidewall 100R includes a second sidewall 102R of the substrate layer 102, a second sidewall 104R of the transparent layer 104, and a second sidewall 108R of the first layer of light shielding material 108. The second sidewall 102R of the substrate layer 102, the second sidewall 104R of the transparent layer 104, and the second sidewall 108R of the first layer of light shielding material 108 are coplanar. The second sidewall 100R is covered by a second portion 116R of the outer layer of light shielding material 116.

The substrate layer 102 may be silicon and may be in the range of 50 and 200 micrometers in thickness. The transparent layer 104 may be glass and may be in the range of 100 and 500 micrometers in thickness.

The sensor elements 106 may be used for light sensing or image sensing in some embodiments. The sensor elements 106 are formed in the substrate layer 102 and are coplanar with the first surface 102a.

The first layer of light shielding material 108 entirely covers the second surface 102b of substrate layer 102 and prevents light from traveling through the substrate layer 102 and reflecting toward the sensor elements 106, generating signal noise.

The TSVs 110 extend through both the first layer of light shielding material 108 and the substrate layer 102. Although only two of the TSVs 110 are shown in FIG. 1, embodiments may include more or fewer TSVs 110. A first portion 120 of each TSV 110 extends from the second surface 102b to the first surface 102a of the substrate layer 102 along a first direction. The first portion 120 may be in the range of 15 and 50 micrometers in thickness along a second direction that is transverse to the first direction. The first portion 120 of each TSV 110 is at least partially filled with air or includes an unfilled gap. According to embodiments, a second portion 122, which can be an opening in the first layer of light shielding material 108, of each TSV 110 extends through the first layer of light shielding material 108 between a first surface 108a and a second surface 108b of the first layer of light shielding material 108. The first surface 108a of the first layer of light shielding material 108 touches the second surface 102b of the substrate layer 102. The second surface 108b of the first layer of light shielding material 108 is between the first surface 108a of the first layer of light shielding material 108 and the second layer of light shielding material. The second portion 122 may be wider than the first portion 120 along the second direction.

Said differently, an opening 126 is formed in the first layer of light shielding material. The opening 126 is wider than the first portion 120 of the TSV 110 in the second direction. The second portion 122 may entirely cover an opening 128 of the first portion 120 and may extend further onto the substrate layer 102 on both sides of the opening of the first portion 120, from a first sidewall 122L to a second sidewall 122R of the second portion 122 of the TSV 110.

A dielectric layer 112, which may be an oxide layer, covers the sidewalls of each first portion 120 and each second portion 122 of each TSV 110. The dielectric layer 112 covers the second surface 108b of the first layer of light shielding material 108. The dielectric layer 112 may extend between multiple TSVs 110. According to an embodiment, the dielectric layer 112 completely covers the second surface 108b and the sidewalls of each first portion 120 and each second portion 122 of each TSV 110.

A redistribution layer 114, which includes conductive and dielectric components, lines the inner surface of each TSV 110. Said differently, the redistribution layer 114 covers the dielectric layer 112 on the sidewalls 120L and 120R of each first portion 120 and the sidewalls 122L and 122R of each second portion 122 of each TSV 110. The redistribution layer 114 also covers an end surface 110a of each TSV 110 that is closest to or at the first surface 102a of the substrate layer 102. In some embodiments, the redistribution layer 114 completely covers the end surface 110a. The redistribution layer 114 extends onto the dielectric layer 112 that is covering the first layer of light shielding material 108, but only partially covers the dielectric layer 112. That is, the redistribution layer 114 does not extend between adjacent TSVs 110. A portion of the dielectric layer 112 between adjacent TSVs 110 remains uncovered by the redistribution layer 114, forming a gap 130 between two contact areas 114c of the redistribution layer 114. The redistribution layer 114 does not extend to the sidewalls 100L and 100R of the electronic device 100. Instead, the redistribution layer 114 extends only partway between each TSV 110 and the sidewalls 100L and 100R.

Contacts 118, which include conductive and dielectric components, are embedded into the substrate layer 102 and are coplanar with the first surface 102a. The contacts 118 are coupled to the redistribution layer 114 on the internal surfaces of the TSVs 110. The contacts 118 may be wider in the second direction than the first portion 120 of each TSV 110.

An outer layer of light shielding material 116 covers the electronic device 110 on five sides. That is, the outer layer of light shielding material 116 covers each of the sidewalls of the electronic device 100, including each sidewall of the transparent layer 104 and each sidewall of the substrate layer 102. As shown in FIG. 1, the first portion 116L of the light shielding material 116 covers the left sidewall 100L of electronic device 100 and the second portion 116R of the light shielding material 116 covers the right sidewall 100R of electronic device 110. The first portion 116L and the second portion 116R of the outer layer of light shielding material 116 may be in the range of 20 and 40 micrometers in thickness.

The outer layer of light shielding material 116 includes a portion 116B on the opposite side of the electronic device 100 than the transparent layer 104 that covers the second surface 102b of the substrate layer 102 and the first layer of light shielding material 108, the dielectric layer 112, and portions of the redistribution layer 114. Portions of the contact areas 114c of the redistribution layer 114 are not covered by the outer layer of light shielding material 116. Solder balls 124 are coupled to the contact areas 114c of the redistribution layer 114, specifically the portions of the contact areas 114c that are not covered by the outer layer of light shielding material 116.

The outer layer of light shielding material 116 prevents light from entering the electronic device 100 through the sidewalls and being detected by sensor elements 106, generating signal noise.

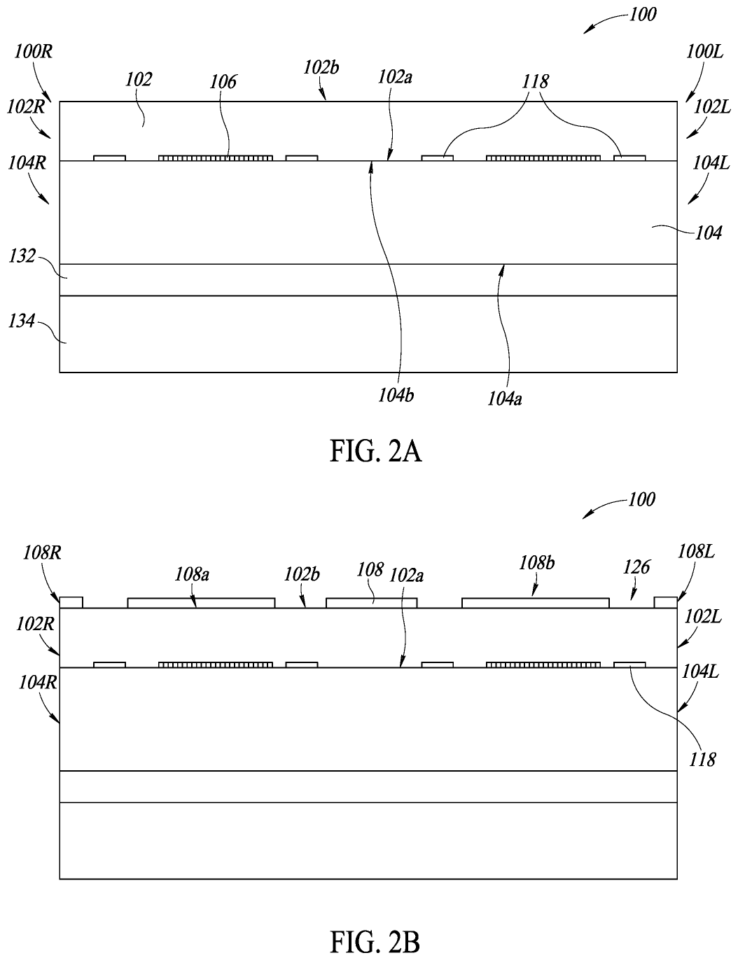

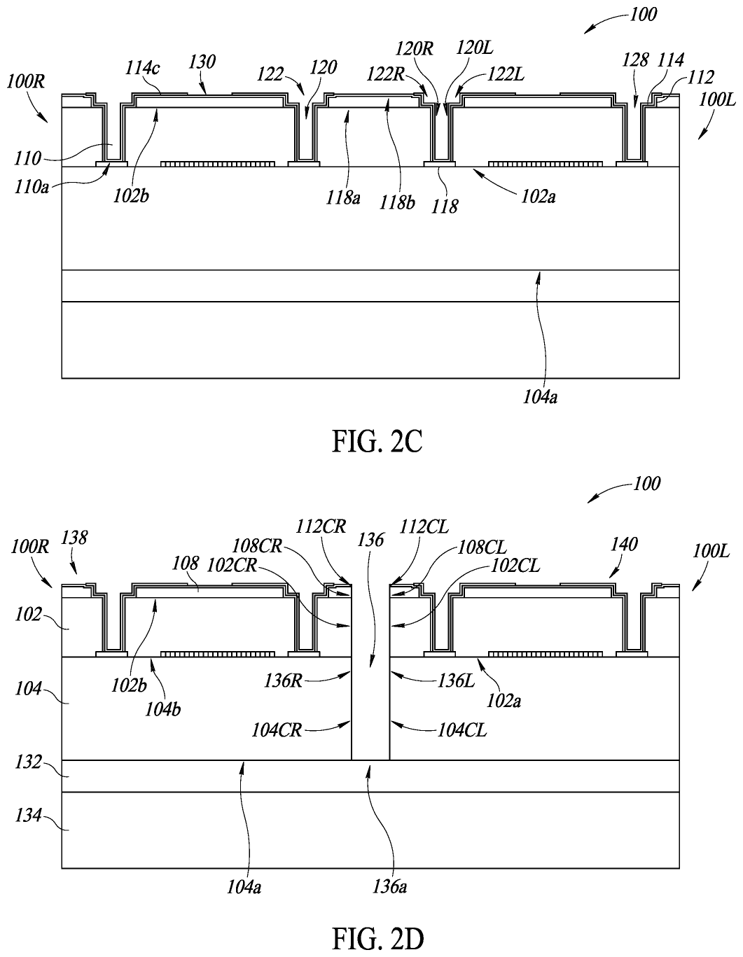

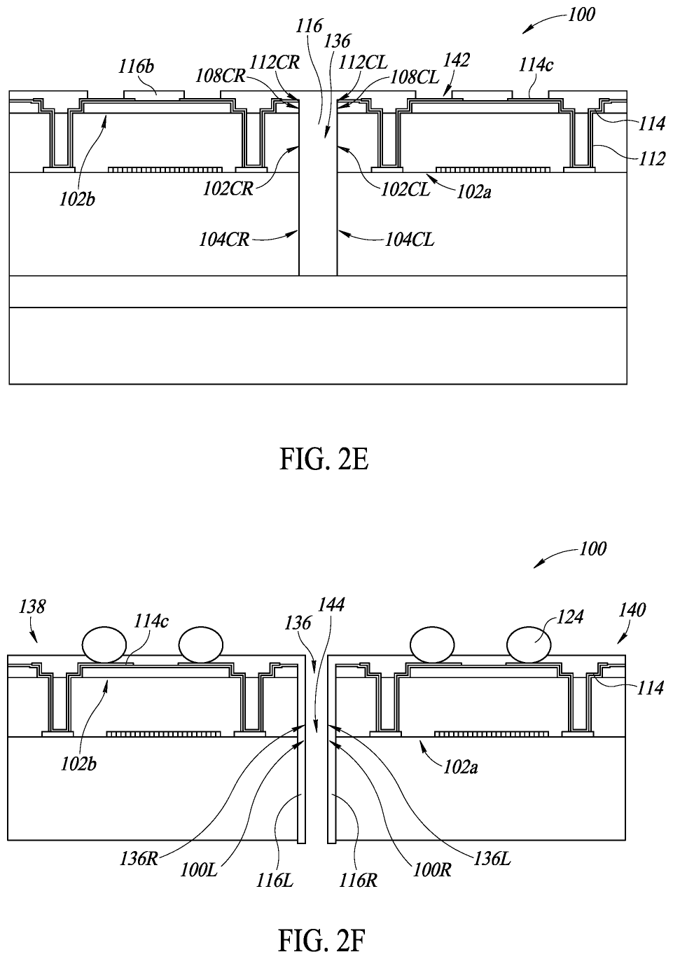

FIG. 2 is a method of assembling the optical sensor package 100 of FIG. 1. The method begins in FIG. 2A with an electronic device 100. The electronic device 100 includes: a substrate layer 102 with a first surface 102a and a second surface 102b; a transparent layer 104 with a first surface 104a and a second surface 104b, where the second surface 104b of the transparent layer 104 touches the first surface 102a of the substrate layer 102; a plurality of sensor elements 106 embedded or otherwise formed in the substrate layer 102, the sensor elements 106 being coplanar with the first surface 102a of the substrate layer 102; a plurality of contacts 118, which include conductive and dielectric components and are embedded or otherwise formed in the substrate layer 102, the contacts 118 being coplanar with the first surface 102a of the substrate layer 102 and with the sensor elements 106; a handling carrier 134, which may provide support for the electronic device during the manufacturing process and reduce the probability of warpage of the transparent layer 104; and a temporary bonding material 132, between the first surface 104a of the transparent layer 104 and the handling carrier 134, which attaches the transparent layer 104 to the handling carrier 134.

A first sidewall 102L of the substrate layer 102 and a first sidewall 104L of the transparent layer 104 are coplanar. A second sidewall 102R of the substrate layer 102 and a second sidewall 104R of the transparent layer 104 are coplanar.

The substrate layer 102 may be silicon and may be in the range of 50 and 200 micrometers in thickness. The transparent layer 104 may be glass and may be in the range of 100 and 500 micrometers in thickness.

Each of the plurality of sensor elements 106 is positioned between two of the plurality of contacts 118. One of the plurality of contacts 118 is positioned between the first sidewall 102L of the substrate layer 102 and the sensor elements 106 that are closest to the first sidewall 102L of the substrate layer 102. One of the plurality of contacts 118 is positioned between the second sidewall 102R of the substrate layer 102 and the sensor elements 106 that are closest to the second sidewall 102R of the substrate layer 102. Two contacts 118 are positioned between adjacent sensor elements 106. While FIG. 2A includes two sensor elements 106 and four contacts 118, embodiments may include more or fewer sensor elements 106. Similarly, embodiments may include more or fewer contacts 118.

With reference to FIG. 2B, a first, inner layer of light shielding material 108 is formed on the second surface 102b of the substrate layer 102. The first layer of light shielding material 108 includes a plurality of openings 126. The plurality of openings 126 are aligned with the plurality of contacts 118 along a first direction. That is, there may be an equal number of openings 126 and contacts 118, with each opening 126 corresponding to one contact 118. While FIG. 2B includes four openings 126, embodiments may include more or fewer openings 126.

The first layer of light shielding material 108 may be formed by spray coating.

A first sidewall 108L of the first layer of light shielding material 108 is coplanar with the first sidewall 102L of the substrate layer 102 and with the first sidewall 104L of the transparent layer 104. A second sidewall 108R of the first layer of light shielding material 108 is coplanar with the second sidewall 102R of the substrate layer 102 and with the second sidewall 104R of the transparent layer 104.

With reference to FIG. 2C, a plurality of TSVs 110 are formed in the substrate layer 102 by a process such as etching. The TSVs 110 are formed in the openings 126 of the first layer of light shielding material 108. Each TSV 110 includes a first portion 120 and a second portion 122. The first portion 120 of each TSV 110 extends along the first direction from the second surface 102b to the contact 118 in the substrate layer 102. The first portion 120 may be in the range of 15 and 50 micrometers in thickness along a second direction that is transverse to the first direction. The second portion 122 of each TSV 110 is the opening 126 in the first layer of light shielding material 108 and extends from the first surface 108a to the second surface 108b of the first layer of light shielding material 108. The first surface 108a of the first layer of light shielding material 108 touches the second surface 102b of the substrate layer 102. The second portion 122 may be wider than the first portion 120 along the second direction. The second portion 122 may entirely cover an opening 128 of the first portion 120 and may extend further onto the substrate layer 102 on both sides of the opening of the first portion 120, from a first sidewall 122L to a second sidewall 122R of the second portion 122 of the TSV 110.

While FIG. 2C includes four TSVs 110, embodiments may include more or fewer TSVS 110.

A dielectric layer 112, which may be an oxide layer, is formed on a first sidewall 120L and a second sidewall 120R of each first portion 120 of each TSV 110, as well as each first and second sidewall, 122L and 112R, of each second portion 122 of each TSV 110. The dielectric layer 112 is formed over the second surface 108b of the first layer of light shielding material 108. The dielectric layer 112 may extend between adjacent TSVs 110. The dielectric layer 112 may not cover an end surface 110a of each TSV 110 that is closest to or at the first surface 102a of the substrate layer 102. According to an embodiment, the dielectric layer 112 completely covers the second surface 108b and the sidewalls of each first portion 120 and each second portion 122 of each TSV 110.

A redistribution layer 114 which includes conductive and dielectric components, is formed on each first and second sidewall, 120L and 120R, of each first portion 120 of each TSV 110, as well as each first and second sidewall, 122L and 112R, of each second portion 122 of each TSV 110. The dielectric layer 112 is between the redistribution layer 114 and the substrate layer 102 in the first portion 120 of each TSV 110. The dielectric layer 112 is between the redistribution layer 114 and the first layer of light shielding material 108. The redistribution layer 114 is also formed on each end surface 110a of each TSV 110. In some embodiments, the redistribution layer 114 completely covers the end surface 110a. The redistribution layer 114 formed on the dielectric layer 112 that is covering the first layer of light shielding material 108 only partially covers the dielectric layer 112. The redistribution layer 114 does not extend fully between adjacent TSVs 110. Rather, a plurality of gaps 130 are formed between adjacent TSVs 110 where a portion of the dielectric layer 112 remains uncovered by the redistribution layer 114. The portions of the redistribution layer 114 on either side of the gaps 130 form a plurality of contact areas 114c. The redistribution layer 114 does not extend to the sidewalls 110L and 110R of the electronic device 100. Instead, the redistribution layer 114 extends only partway between each TSV 110 and the sidewalls 100L and 100R of the electronic device 100.

The redistribution layer 114 may be metal and may be formed by processes such as photolithography or plating.

With reference to FIG. 2D, a first cavity 136 is formed between two of the plurality of TSVs 110. The first cavity 136 extends in the first direction through the entirety of the dielectric layer 112, the entirety of the first layer of light shielding material 108, the entirety of the substrate layer 102, and the entirety of the transparent layer 104. The first cavity 136 includes an end surface 136a that may be coplanar with the first surface 104a of the transparent layer 104. According to an embodiment, the first cavity 136 may extend in the first direction through a portion of the temporary bonding material 132 or through the entirety of the temporary bonding material 132. According to an embodiment, the first cavity 136 may extend in the first direction through a portion of the handling carrier 134.

The first cavity 136 separates a first die 138 from a second die 140. The second die 140 extends along the first direction from the redistribution layer 114 to the first surface 104a of the transparent layer 104. The second die 140 extends along the second direction from a first sidewall 136L of the first cavity 136 to the first sidewall 100L of the electronic device 100. The first sidewall 136L of the first cavity 136 includes a first central sidewall 104CL of the transparent layer 104, a first central sidewall 102CL of the substrate layer 102, a first central sidewall 108CL of the first layer of light shielding material 108, and a first central sidewall 112CL of the dielectric layer 112, all of which are coplanar. The first die extends along the first direction from the redistribution layer 114 to the first surface 104a of the transparent layer 104. The first die 138 extends along the second direction from the second sidewall 100R of the electronic device 100 to a second sidewall 136R of the first cavity 136. The second sidewall 136R of the first cavity 136 includes a second central sidewall 104CR of the transparent layer 104, a second central sidewall 102CR of the substrate layer 102, a second central sidewall 108CR of the first layer of light shielding material 108, and a first central sidewall 112CR of the dielectric layer 112, all of which are coplanar.

The first cavity 136 may be formed by a saw, a laser, or another cutting process.

With reference to FIG. 2E, a second, outer layer of light shielding material 116 is formed. The second layer of light shielding material 116 fills the first cavity 136. According to an embodiment, the second layer of light shielding material 116 completely fills the first cavity 136. The second layer of light shielding material 116 covers the first and second central sidewalls 104CL and 104CR of the transparent layer 104, the first and second central sidewalls 102CL, 102CR of the substrate layer 102, the first and second central sidewalls 108CL, 108CR of the first layer of light shielding material 108, and the first and second central sidewalls 112CL, 112CR of the dielectric layer 112.

The second layer of light shielding material 116 includes a portion 116B that is formed on a side of the electronic device 100 opposite the handling carrier 134. The portion 116B of the second layer of light shielding material 116 covers the second surface 102b of the substrate layer 102 and the first layer of light shielding material 108, the dielectric layer 112, and portions of the redistribution layer 114.

The second layer of light shielding material 116 may be formed by spray coating.

The first portions 120 of each TSV 110 are at least partially filled with air or include an unfilled gap. According to embodiments, the second layer of light shielding material 116 at least partially fills the second portions 122 of each TSV 110.

A plurality of openings 142 are formed in the second layer of light shielding material 116 to expose the contact areas 114c of the redistribution layer 114.

With reference to FIG. 2F, a plurality of solder balls 124 are formed on the contact areas 114c of the redistribution layer 114. The plurality of solder balls 124 are conductive. According to an embodiment, the plurality of solder balls 124 completely fills the plurality of openings 142 in the second layer of light shielding material 116.

A second cavity 144 is formed in the second layer of light shielding material 116 in the first cavity 136. The second cavity 144 extends in the first direction through the entirety of the dielectric layer 112, the entirety of the first layer of light shielding material 108, the entirety of the substrate layer 102, and the entirety of the transparent layer 104. After the second cavity 144 is formed, the first sidewall 136L and the second sidewall 136R of the first cavity 136 remain covered in the second layer of light shielding material 116, forming a first portion 116L covering the second sidewall 136R of the first cavity 136 and a second portion 116L covering the first sidewall 136L of the first cavity 136. The first portion 116L and the second portion 116R of the second layer of light shielding material 116 may be in the range of 20 and 40 micrometers in thickness. The second cavity 144 completely separates the first die 138 from the second die 140.

The second cavity 144 may be formed by a saw, a laser, or another cutting process.

Although only two die, the first die 138 and the second die 140, are shown in FIG. 2F, embodiments may include more die.

The temporary bonding material 132 and handling carrier 134 are removed from the electronic device 100. The removal of the temporary bonding material 133 and the handling carrier 134 may be removed prior to the forming of the second cavity 144 or after the forming of the second cavity 144, according to embodiments.

The present disclosure is directed to a device that includes a substrate that includes a first surface opposite to a second surface. The substrate includes a plurality of sidewalls that extend from the first surface to the second surface and a plurality of sensor elements in the first surface. A first through silicon via that extends from the second surface to the first surface. A transparent layer on the first surface of the substrate, the transparent layer including an exposed surface that is opposite to the first surface of the substrate and a plurality of sidewalls that extend from the exposed surface to the first surface of the substrate. A first layer of light shielding material that covers the second surface of the substrate, the plurality of sidewalls of the substrate, and the plurality of sidewalls of the transparent layer. The light shielding material completely covers the plurality of sidewalls of the substrate and completely covers the plurality of sidewalls of the transparent layer.

The plurality of sidewalls of the substrate are coplanar with the plurality of sidewalls of the transparent layer. A second through silicon via from the second surface to the first surface, the plurality of sensor elements being between the first through silicon via and the second through silicon via. The transparent layer is glass. A second layer of light shielding material coupled between the first layer of light shielding material and the second surface of the substrate.

A dielectric layer completely covering an internal surface of the first through silicon via, the dielectric layer being between the first layer of light shielding material and the second layer of light shielding material. A redistribution layer completely covering the internal surface of the first through silicon via, the redistribution layer being between the dielectric layer and the first layer of light shielding material. A contact between the first surface of the substrate and the transparent layer and coupled to the redistribution layer on the internal surface of the first through silicon via.

The present disclosure includes forming a first layer of light shielding material covering a first surface of a substrate and forming a first opening completely through the substrate and a transparent layer coupled to the substrate. The method includes forming a second layer of light shielding material in the first opening and on the first layer of light shielding material and forming a second opening in the second layer of light shielding material that is in the first opening. The method includes forming a plurality of through silicon vias that extend from the first surface of the substrate to the transparent layer. The method also includes forming a dielectric layer in the plurality of through silicon vias and on the first layer of light shielding material.

The method includes forming a redistribution layer in the plurality of through silicon vias and partially covering the first layer of light shielding material. The second layer of light shielding material entirely fills the first opening. The method includes forming solder balls coupled to the redistribution layer. The method includes forming a plurality of gaps in the first layer of light shielding material, each of the plurality of gaps being directly over one of the plurality of through silicon vias and being wider than each of the plurality of through silicon vias. The method includes the second layer of light shielding material fills each of the plurality of gaps in the first layer of light shielding material.

The present disclosure includes a device that includes a substrate that includes a first surface opposite to a second surface and a transparent layer on the first surface of the substrate. The transparent layer including an exposed surface that is opposite to the first surface of the substrate and a plurality of sidewalls that extend from the exposed surface to the first surface of the substrate. The device includes a first layer of light shielding material that covers the second surface of the substrate, the plurality of sidewalls of the substrate, and the plurality of sidewalls of the transparent layer and a second layer of light shielding material that is between the first layer of light shielding material and the second surface. A first through silicon via that extends along a first direction through the second layer of light shielding material to the first surface, the first through silicon via including a first portion that extends along the first direction from the second surface to the first surface and has a first width along a second direction that is transverse to the first direction and a second portion that extends along the first direction through the second layer of light shielding material to the second surface, the second portion having a second width along the second direction that is greater than the first width of the first portion. The device includes a first portion of the second layer of light shielding material extends into the second portion of the first through silicon via. The device includes an air gap in the first through silicon via between the first portion of the second layer of light shielding material and the first surface.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications, and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a substrate that includes a first surface opposite to a second surface, the substrate including:
a plurality of sidewalls that extend from the first surface to the second surface;
a plurality of sensor elements in the first surface;
a first through silicon via that extends from the second surface to the first surface;
a transparent layer on the first surface of the substrate, the transparent layer including:
an exposed surface that is opposite to the first surface of the substrate; and
a plurality of sidewalls that extend from the exposed surface to the first surface of the substrate;
a first layer of light shielding material that covers the second surface of the substrate, the plurality of sidewalls of the substrate, and the plurality of sidewalls of the transparent layer.

2. The device of claim 1, wherein the light shielding material completely covers the plurality of sidewalls of the substrate and completely covers the plurality of sidewalls of the transparent layer.

3. The device of claim 1, wherein the plurality of sidewalls of the substrate are coplanar with the plurality of sidewalls of the transparent layer.

4. The device of claim 1, comprising a second through silicon via from the second surface to the first surface, the plurality of sensor elements being between the first through silicon via and the second through silicon via.

5. The device of claim 1, wherein the transparent layer is glass.

6. The device of claim 1, comprising a second layer of light shielding material coupled between the first layer of light shielding material and the second surface of the substrate.

7. The device of claim 6, comprising a dielectric layer completely covering an internal surface of the first through silicon via, the dielectric layer being between the first layer of light shielding material and the second layer of light shielding material.

8. The device of claim 7, comprising a redistribution layer completely covering the internal surface of the first through silicon via, the redistribution layer being between the dielectric layer and the first layer of light shielding material.

9. The device of claim 8, comprising a contact between the first surface of the substrate and the transparent layer and coupled to the redistribution layer on the internal surface of the first through silicon via.

10. A method, comprising:
forming a first layer of light shielding material covering a first surface of a substrate;
forming a first opening completely through the substrate and a transparent layer coupled to the substrate;
forming a second layer of light shielding material in the first opening and on the first layer of light shielding material; and
forming a second opening in the second layer of light shielding material that is in the first opening.

11. The method of claim 10, comprising forming a plurality of through silicon vias that extend from the first surface of the substrate to the transparent layer.

12. The method of claim 11, comprising forming a dielectric layer in the plurality of through silicon vias and on the first layer of light shielding material.

13. The method of claim 11, comprising forming a redistribution layer in the plurality of through silicon vias and partially covering the first layer of light shielding material.

14. The method of claim 10, wherein the second layer of light shielding material entirely fills the first opening.

15. The method of claim 13, comprising forming solder balls coupled to the redistribution layer.

16. The method of claim 11, comprising forming a plurality of gaps in the first layer of light shielding material, each of the plurality of gaps being directly over one of the plurality of through silicon vias and being wider than each of the plurality of through silicon vias.

17. The method of claim 16, wherein the second layer of light shielding material fills each of the plurality of gaps in the first layer of light shielding material.

18. A device, comprising:
a substrate that includes a first surface opposite to a second surface;
a transparent layer on the first surface of the substrate, the transparent layer including:
an exposed surface that is opposite to the first surface of the substrate; and
a plurality of sidewalls that extend from the exposed surface to the first surface of the substrate;
a first layer of light shielding material that covers the second surface of the substrate, the plurality of sidewalls of the substrate, and the plurality of sidewalls of the transparent layer;
a second layer of light shielding material that is between the first layer of light shielding material and the second surface;
a first through silicon via that extends along a first direction through the second layer of light shielding material to the first surface, the first through silicon via including:
a first portion that extends along the first direction from the second surface to the first surface and has a first width along a second direction that is transverse to the first direction; and
a second portion that extends along the first direction through the second layer of light shielding material to the second surface, the second portion having a second width along the second direction that is greater than the first width of the first portion.

19. The device of claim 18, wherein a first portion of the second layer of light shielding material extends into the second portion of the first through silicon via.

20. The device of claim 19, comprising an air gap in the first through silicon via between the first portion of the second layer of light shielding material and the first surface.
